(19) United States
(12) Patent Application Publication
(10) Pub. No.: US 2013/0112970 A1
(43) Pub. Date: May 9, 2013

(54) THIN FILM TRANSISTOR SUBSTRATE AND FABRICATION METHOD FOR THE SAME

(71) Applicants: Yoshinobu Miyamoto, Osaka-shi (JP); Okifumi Nakagawa, Osaka-shi (JP); Yoshifumi Ohta, Osaka-shi (JP); Yuuji Mizuno, Osaka-shi (JP); Yoshimasa Chikama, Osaka-shi (JP); Tokuo Yoshida, Osaka-shi (JP); Masahiko Suzuki, Osaka-shi (JP); Yoshiyuki Harumoto, Osaka-shi (JP); Tetsuya Yamashita, Osaka-shi (JP)

(72) Inventors: Yoshinobu Miyamoto, Osaka-shi (JP); Okifumi Nakagawa, Osaka-shi (JP); Yoshifumi Ohta, Osaka-shi (JP); Yuuji Mizuno, Osaka-shi (JP); Yoshimasa Chikama, Osaka-shi (JP); Tokuo Yoshida, Osaka-shi (JP); Masahiko Suzuki, Osaka-shi (JP); Yoshiyuki Harumoto, Osaka-shi (JP); Tetsuya Yamashita, Osaka-shi (JP)

(21) Appl. No.: 13/701,549

(22) PCT Filed: Jun. 6, 2011
(86) PCT No.: PCT/JP2011/003179

§ 371 Date: Dec. 3, 2012

(30) Foreign Application Priority Data
Jun. 7, 2010 (JP) 2010-129976

(51) Int. Cl. H01L 29/786; H01L 29/66

(52) U.S. Cl. CPC H01L 29/786; H01L 29/66969
USPC 257/43; 438/151

(57) ABSTRACT

A TFT substrate (30a) including a TFT (5a) having: a gate electrode (14a) provided on a substrate (10a); a gate insulating film (15) provided to cover the gate electrode (14a); a semiconductor layer (16a) made of an oxide semiconductor provided on the gate insulating film (15) with a channel region (C) arranged to lie above the gate electrode (14a): and a source electrode (19aa) and a drain electrode (19b) provided on the semiconductor layer (16a) to be spaced from each other with the channel region (C) therebetween. A recess (R) is provided on the surface of the channel region (C) of the semiconductor layer (16a) to extend in the channel width direction.

### TECHNICAL FIELD

The present disclosure relates to a thin film transistor substrate and a fabrication method for the same, and more particularly to a thin film transistor substrate having thin film transistors using a semiconductor layer made of an oxide semiconductor and a fabrication method for the same.

### BACKGROUND ART

A display panel of an active matrix drive scheme includes a thin film transistor (hereinafter also referred to as a “TFT”) substrate having a TFT as a switching element for each pixel that is the minimum unit of an image.

For example, Patent Document 1 discloses a fabrication method for TFTs, where a semiconductor thin film is formed on a glass substrate via a gate electrode and a gate insulating film, a channel protection film is formed on the semiconductor thin film, the semiconductor thin film is then dry-etched using the channel protection film as a mask until the thickness thereof is approximately halved, and thereafter source and drain electrodes are formed on the semiconductor thin film via an ohmic layer. Patent Document 1 describes that, by the above method, the source and drain electrodes can be formed, via the ohmic layer, on a clean surface of the semiconductor thin film with any oxide film or polluted portion removed from the surface, and thus the transistor characteristics can be stabilized.

### CITATION LIST

### Patent Document

PATENT DOCUMENT 1: Japanese Patent Publication No. H09-270517

### SUMMARY OF THE INVENTION

### Technical Problem

In recent years, in a TFT substrate, it has been proposed to use, in place of conventional TFTs using a semiconductor layer made of amorphous silicon, TFTs using a semiconductor layer made of an oxide semiconductor (hereinafter also referred to as an “oxide semiconductor layer”) that exhibit good characteristics such as high mobility, high reliability, and reduced OFF current.

A bottom-gate TFT using an oxide semiconductor layer includes, for example: a gate electrode provided on a glass substrate; a gate insulating film provided to cover the gate electrode; an island-like oxide semiconductor layer provided on the gate insulating film to lie above the gate electrode; a source electrode and a drain electrode provided on the oxide semiconductor layer to be spaced from each other. In such a TFT using an oxide semiconductor layer, the portion of the surface of the oxide semiconductor layer that is not covered with the source electrode or the drain electrode may become conductive, for example, due to reduction reaction occurring in a sputtering process, causing failure to secure a good ON/OFF ratio.

In view of the above problem, it is an objective of the present disclosure to secure a good ON/OFF ratio in TFTs using an oxide semiconductor layer.

### Solution To The Problem

To attain the above objective, according to the present disclosure, a recess is provided on the surface of a channel region of the semiconductor layer made of an oxide semiconductor to extend in the channel width direction.

Specifically, the thin film transistor substrate of the present disclosure includes a thin film transistor having: a gate electrode provided on a substrate; a gate insulating film provided to cover the gate electrode; a semiconductor layer made of an oxide semiconductor provided on the gate insulating film with a channel region arranged to lie above the gate electrode; and a source electrode and a drain electrode provided on the semiconductor layer to be spaced from each other with the channel region therebetween, wherein a recess is provided on the surface of the channel region of the semiconductor layer to extend in a channel width direction.

According to the above configuration, a recess is provided on the surface of the channel region of the semiconductor layer made of an organic semiconductor to extend in the channel width direction. Therefore, a channel current (OFF current) does not easily flow on the surface of the semiconductor layer when no voltage is being applied between the gate electrode and the semiconductor layer. When a voltage is being applied between the gate electrode and the semiconductor layer, a channel current (ON current) flows on the surface of the semiconductor layer via the bottom of the recess of the semiconductor layer. Thus, since the OFF current is suppressed or reduced while the ON current is maintained, a good ON/OFF ratio is secured in the TFT using an oxide semiconductor layer.

The recess may be provided on the entire of a portion of the semiconductor layer that is not covered with the source electrode or the drain electrode.

According to the above configuration, since the entire of a portion of the semiconductor layer that is not covered with the source electrode or the drain electrode is recessed, the source electrode and the drain electrode serve as a mask for formation of the recess. This eliminates the necessity of forming a mask for formation of a recess separately, and thus suppresses or reduces increases in the number of fabrication steps and the fabrication cost.

The semiconductor layer may have semiconductivity at the bottom of the recess and have conductivity at edges of the recess.

According to the above configuration, where the semiconductor layer has semiconductivity at the bottom of the recess and conductivity at the edges of the recess, while a channel current (ON current) flows via the bottom of the recess of the semiconductor layer, which has semiconductivity, when a voltage is being applied between the gate electrode and the semiconductor layer, flow of a channel current (OFF current) is suppressed or reduced by the recess of the semiconductor layer and the bottom of the recess having semiconductivity when no voltage is being applied between the gate electrode and the semiconductor layer.

The fabrication method for a thin film transistor substrate of the present disclosure includes: a gate formation step of forming a gate electrode on a substrate; a semiconductor layer formation step of, after formation of a gate insulating film to cover the gate electrode, forming a semiconductor layer made of an oxide semiconductor on the gate insulating film with a channel region arranged to lie above the gate electrode; and a source/drain formation step of forming a source electrode and a drain electrode on the semiconductor layer to be spaced from each other with the channel region therebetween, wherein the method further includes a recess formation step of forming a recess on the surface of the channel region of the semiconductor layer to extend in a channel width direction, to reduce or prevent short-circuiting between the source electrode and the drain electrode.

According to the above method, in the recess formation step, the recess (for reduction or prevention of short-circuiting between the source electrode and the drain electrode) is formed on the surface of the channel region of the semiconductor layer made of an oxide semiconductor to extend in the channel width direction. Therefore, a channel current (OFF current) does not flow easily on the surface of the semiconductor layer when no voltage is being applied between the gate electrode and the semiconductor layer. When a voltage is being applied between the gate electrode and the semiconductor layer, a channel current (ON current) flows on the surface of the semiconductor layer via the bottom of the recess of the semiconductor layer. Thus, since the OFF current is suppressed or reduced while the ON current is maintained, a good ON/OFF ratio is secured in the TFT using an oxide semiconductor layer.

In the recess formation step, the semiconductor layer may be etched using the source electrode and the drain electrode as a mask.

According to the above method, since the semiconductor layer is etched using the source electrode and the drain electrode as a mask to form the recess of the semiconductor layer in the recess formation step, it is unnecessary to form a mask for formation of a recess separately, and thus increases in the number of fabrication steps and the fabrication cost are suppressed or reduced.

### Advantages of the Invention

According to the present disclosure, a recess is provided on the surface of the channel region of the semiconductor layer made of an oxide semiconductor to extend in the channel width direction. Therefore, a good ON/OFF ratio can be secured in the TFT using the oxide semiconductor layer.

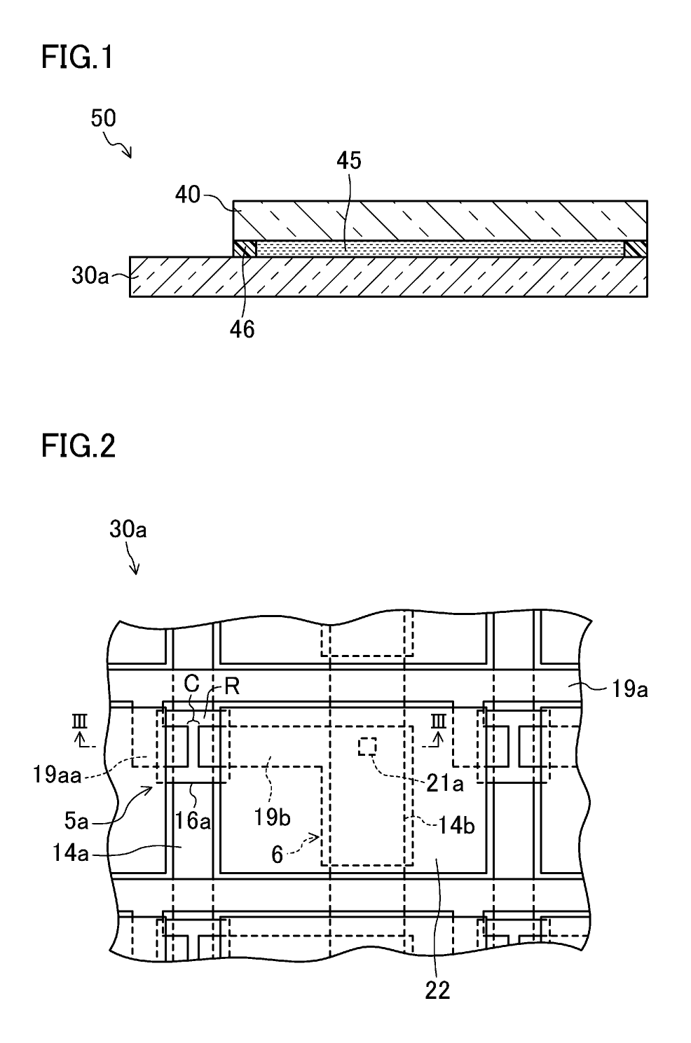

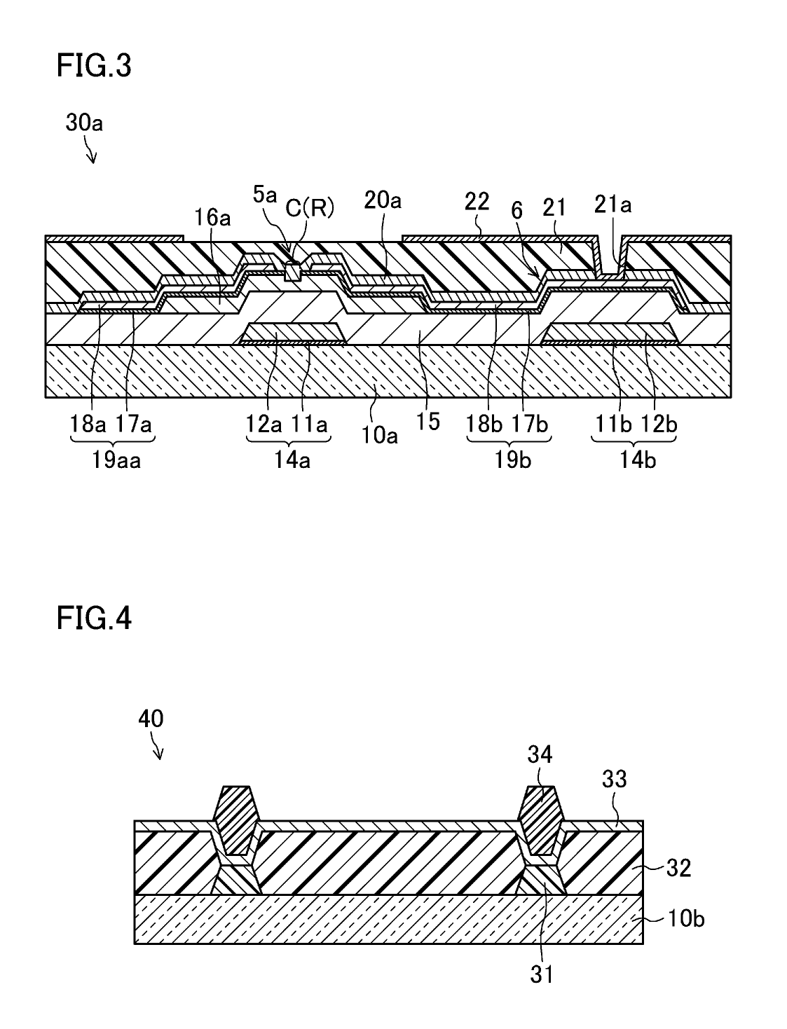

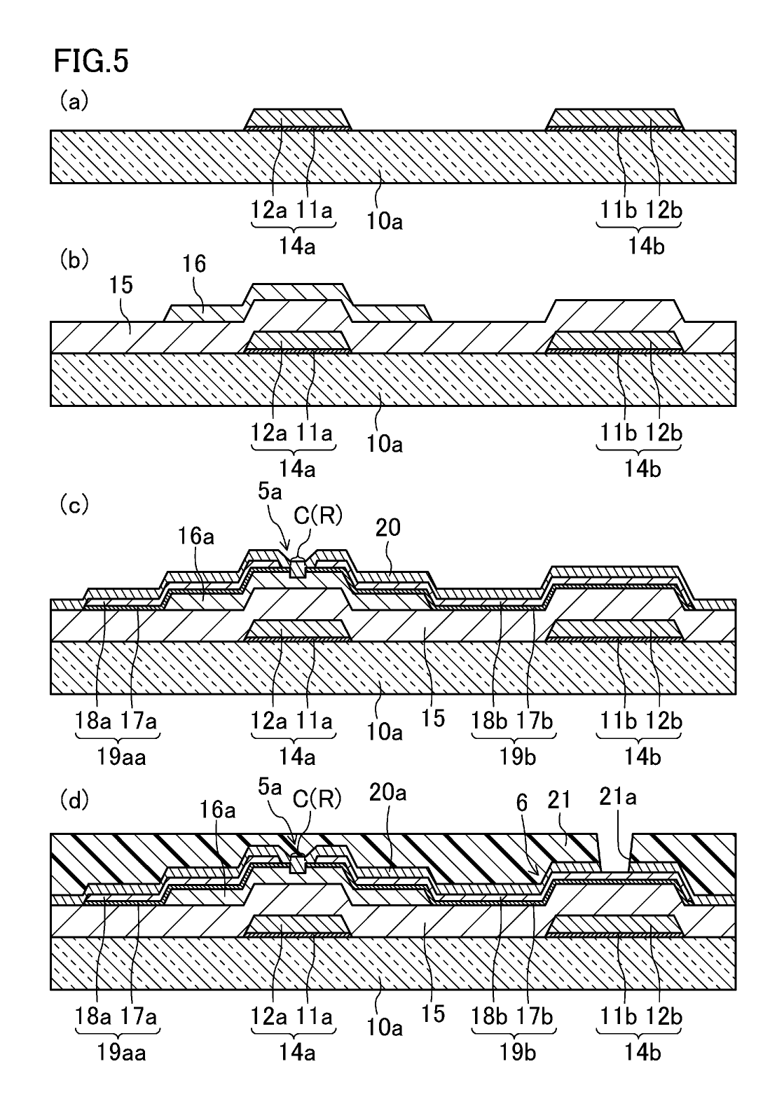

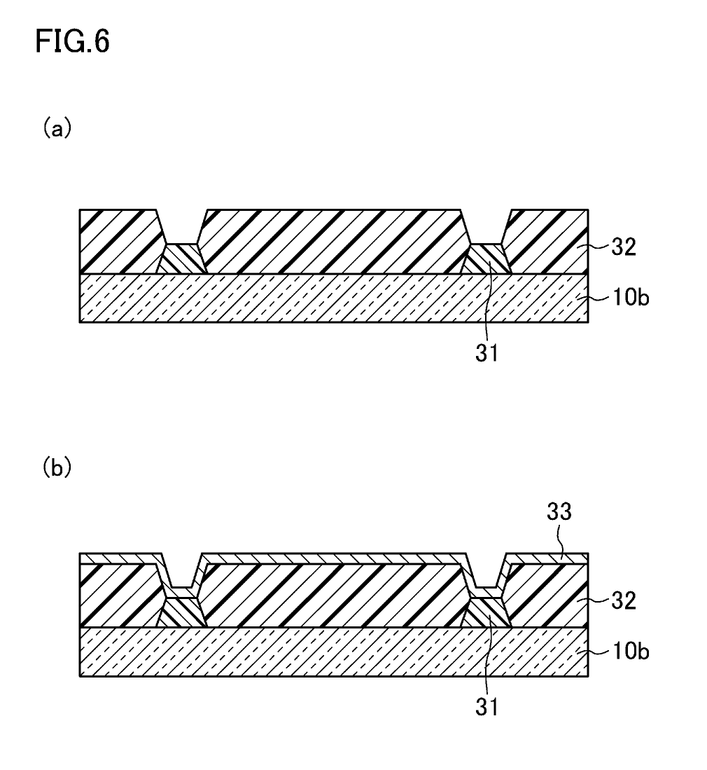

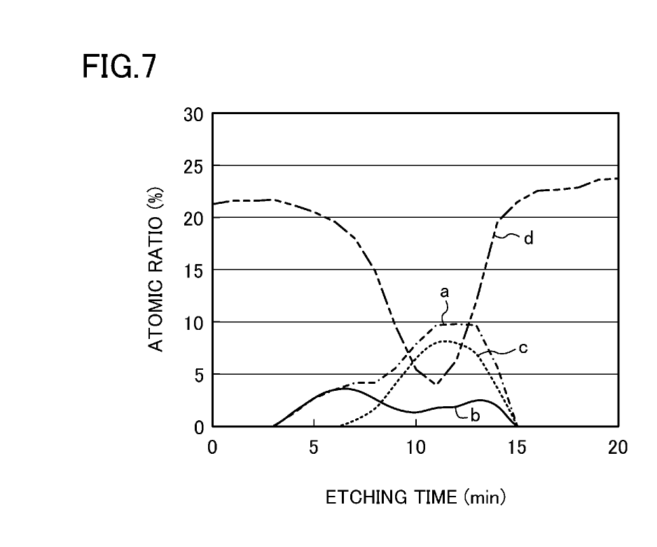

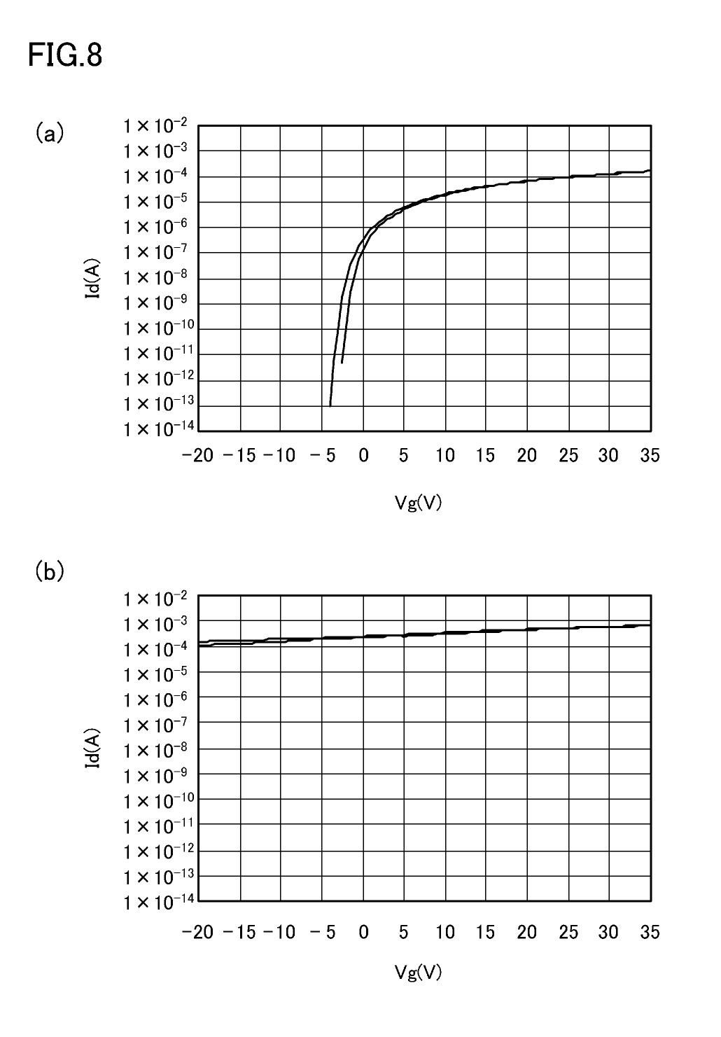

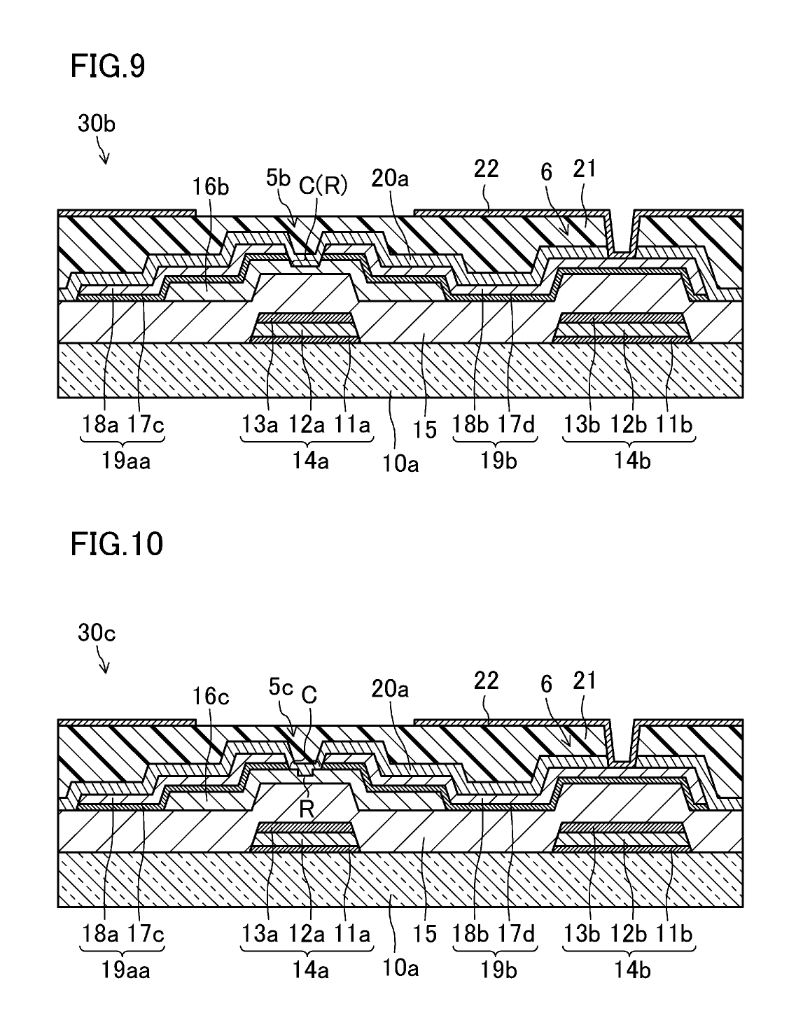

### BRIEF DESCRIPTION OF THE DRAWINGS

[FIG. 1] FIG. 1 is a cross-sectional view showing a liquid crystal display panel including a TFT substrate of Embodiment 1.

[FIG. 2] FIG. 2 is a plan view of the TFT substrate of Embodiment 1.

[FIG. 3] FIG. 3 is a cross-sectional view of the TFT substrate taken along line III-III in FIG. 2.

[FIG. 4] FIG. 4 is a cross-sectional view of a counter substrate constituting the liquid crystal display panel in Embodiment 1.

[FIG. 5] FIGS. 5(a) to 5(d) are explanatory views showing, in cross section, a fabrication process for the TFT substrate of Embodiment 1.

[FIG. 6] FIGS. 6(a) and 6(b) are explanatory views showing, in cross section, a fabrication process for the counter substrate in Embodiment 1.

[FIG. 7] FIG. 7 is a graph showing the relationship between the etching time and the element composition ratio in the first experimental example.

[FIG. 8] FIGS. 8(a) and 8(b) are graphs showing a TFT characteristic in the second experimental example.

[FIG. 9] FIG. 9 is a cross-sectional view of a TFT substrate of Embodiment 2.

[FIG. 10] FIG. 10 is a cross-sectional view of a TFT substrate of Embodiment 3.

### DESCRIPTION OF EMBODIMENTS

Embodiments of the present disclosure will be described hereinafter with reference to the accompanying drawings. It should be noted that the present disclosure is not limited to the embodiments to follow.

### Embodiment 1

FIGS. 1 to 8 show a TFT substrate and a fabrication method for the same of Embodiment 1 of the present disclosure. Specifically, FIG. 1 is a cross-sectional view showing a liquid crystal display panel 50 including a TFT substrate 30a of this embodiment. FIG. 2 is a plan view of the TFT substrate 30a of this embodiment, and FIG. 3 is a cross-sectional view of the TFT substrate 30a taken along line III-III in FIG. 2. FIG. 4 is a cross-sectional view of a counter substrate 40 constituting the liquid crystal display panel 50 in this embodiment.

As shown in FIG. 1, the liquid crystal display panel 50 includes the TFT substrate 30a and the counter substrate 40 placed to face each other, a liquid crystal layer 45 provided between the TFT substrate 30a and the counter substrate 40, and a seal material 46 provided in a frame shape to bond the TFT substrate 30a and the counter substrate 40 together, and to seal the liquid crystal layer 45 between the TFT substrate 30a and the counter substrate 40.

As shown in FIGS. 2 and 3, the TFT substrate 30a includes: an insulating substrate 10a; a plurality of gate lines 14a provided on the insulating substrate 10a to extend in parallel with each other; a plurality of capacitor lines 14b provided between the adjacent gate lines 14a to extend in parallel with each other; a gate insulating film 15 provided to cover the gate lines 14a and the capacitor lines 14b; a plurality of source lines 19a provided on the gate insulating film 15 to extend in parallel with each other in a direction orthogonal to the gate lines 14a; a plurality of TFTs 5a each provided at each of the intersections of the gate lines 14a and the source lines 18a, i.e., provided for each pixel that is the minimum unit of an image; a protection film 20a provided to cover the TFTs 5a; an interlayer insulating film 21 provided on the protection film 20a; a plurality of pixel electrodes 22 provided in a matrix on the interlayer insulating film 21; and an alignment film (not shown) provided to cover the pixel electrodes 22.

As shown in FIGS. 2 and 3, each of the TFTs 5a includes: a gate electrode (14a) provided on the insulating substrate 10a; the gate insulating film 15 provided to cover the gate electrode (14a); a semiconductor layer 16a provided on the gate insulating film 15 with a channel region C arranged to lie above the gate electrode (14a); and a source electrode 19aa and a drain electrode 19b provided on the semiconductor layer 16a to be spaced from each other with the channel region C therebetween.

The gate electrode (14a) is a portion of the corresponding gate line 14a as shown in FIG. 2. The gate electrode (14a), i.e., the gate line 14a has a layered structure of a first metal layer 11a and a second metal layer 12a formed in this order as shown in FIG. 3. Like the gate line 14a, each capacitor line 14b has a layered structure of a first metal layer 11b and a second metal layer 12b formed in this order as shown in FIG. 3.

The source electrode 19aa is an L-shaped protrusion from the corresponding source line 19a as shown in FIG. 2. The source electrode 19aa and the source line 19a have a layered structure of a first metal layer 17a and a second metal layer 18a formed in this order as shown in FIG. 3.

The drain electrode 19b is connected to the pixel electrode 22 via a contact hole 21a formed through the protection film 20a and the interlayer insulating film 21 as shown in FIG. 3, and lies above the capacitor line 14b via the gate insulating film 15 to constitute a storage capacitor 6 as shown in FIGS. 2 and 3. Also, the drain electrode 19b has a layered structure of a first metal layer 17b and a second metal layer 18b formed in this order as shown in FIG. 3.

The semiconductor layer 16a is made of an In—Ga—Zn—O oxide semiconductor, for example. On the semiconductor layer 16a, a recess R is provided on the surface of the channel region C arranged between the source electrode 19aa and the drain electrode 19b to extend in the channel width direction, as shown in FIG. 2. The recess R is provided on the entire of the portion of the semiconductor layer 16a that is not covered with the source electrode 19aa and the drain electrode 19a, and thus has an H shape as viewed from top, as shown in FIG. 2.

As shown in FIG. 4, the counter substrate 40 includes: an insulating substrate 10b; a black matrix 31 provided on the insulating film 10b in a lattice shape; a plurality of colored layers 32 such as red layers, green layers, blue layers, etc. provided in the interstices of the lattice of the black matrix 31; a common electrode 33 provided to cover the black matrix 31 and the colored layers 32; photo spacers 34 provided in a shape of columns on the common electrode 33; and an alignment film (not show) provided to cover the common electrode 33.

The liquid crystal layer 45 is made of a nematic liquid crystal material having electrooptic characteristics, etc.

In the liquid crystal display panel 50 having the configuration described above, a predetermined voltage is applied for each pixel across the liquid crystal layer 45 placed between each pixel electrode 22 of the TFT substrate 30a and the common electrode 33 of the counter substrate 40, to change the aligned state of the liquid crystal layer 45, whereby the transmittance of light passing through the panel is adjusted for each pixel, and thus an image is displayed.

Next, a fabrication method for the liquid crystal display panel 50 in this embodiment will be described with reference to FIGS. 5 and 6. FIGS. 5(a) to 5(d) are explanatory views showing, in cross section in correspondence with the cross-sectional view of FIG. 3, the fabrication process for the TFT substrate 30a of this embodiment. FIGS. 6(a) to 6(d) are explanatory views showing, in cross section in correspondence with the cross-sectional view of FIG. 4, the fabrication process for the counter substrate 40 in this embodiment. The fabrication method for the liquid crystal display panel 50 in this embodiment includes a TFT substrate fabrication process including a gate formation step, a semiconductor layer formation step, a source/drain formation step, and a recess formation step, a counter substrate fabrication process, and a liquid crystal injection process.

<TFT Substrate Fabrication Process>

First, a first metal film (thickness: about 30 nm to 150 nm) such as a titanium film and a second metal film (thickness: about 100 nm to 600 nm) such as an aluminum film or a copper film, for example, are formed in this order on the entire of the insulating substrate 10a such as a glass substrate by sputtering. The resultant metal layered film is then subjected to photolithography, wet etching, resist removal, and cleaning, to form the gate lines 14a, the gate electrodes (14a), and the capacitor lines 14b as shown in FIG. 5(a) (gate formation step).

Subsequently, a silicon nitride film (thickness: about 100 nm to 500 nm) or a layered film of a silicon oxide film and a silicon nitride film, for example, is formed on the entire substrate having the gate lines 14a, the gate electrodes (14a), and the capacitor lines 14b formed thereon by chemical vapor deposition (CVD), to form the gate insulating film 15. Further, an In—Ga—Zn—O oxide semiconductor film (thickness: about 5 nm to 300 nm) is formed by sputtering, and then subjected to photolithography, wet etching, resist removal, and cleaning, to form semiconductor layers 16 as shown in FIG. 5(b) (semiconductor layer formation step).

Thereafter, a first metal film (thickness: about 30 nm to 150 nm) such as a titanium film and a second metal film (thickness: about 50 nm to 600 nm) such as an aluminum film, for example, are formed in this order on the entire substrate having the semiconductor layers 16 formed thereon by sputtering. The second metal film is then subjected to photolithography, wet etching, resist removal, and cleaning, to form the second metal layers 18a and 18b. Further, the first metal film and upper portions of the underlying semiconductor layers 16 are dry-etched using boron trichloride gas (270 sccm) and chlorine gas (90 sccm) under a chamber vacuum of 1.6 Pa and high-frequency power of 1500 W, for example, to form the first metal layers 17a and 17b, thereby forming the source lines 19a, the source electrodes 19aa, and the drain electrodes 19b (source/drain formation step) and also forming the recesses R on the surfaces of the channel regions C of the semiconductor layers 16 (recess formation step), as shown in FIG. 5(c). In this way, the semiconductor layers 16a each having the recess R, and the TFTs 5a including the same, are formed. The sccm stands for the “standard cubic centimeters per minute” that is a unit indicating the flow (cc) per minute. Note that the gas flows and the values of the high-frequency power presented above are mere examples, which depend on the sizes, etc. of the chamber and the substrate.

Subsequently, an inorganic insulating film 20 made of a silicon oxide film, etc. (thickness: about 10 nm to 500 nm) is formed on the entire substrate having the TFTs 5a formed thereon by CVD, for example, as shown in FIG. 5(c).

A photosensitive resin is then applied to a thickness of about 1.0 μm to 3.0 μm to the entire substrate having the inorganic insulating film 20 formed thereon by spin coating or slit coating, for example, and the resultant applied film is patterned by photolithography, to form the interlayer insulating film 21 having the contact holes 21a. Thereafter, the inorganic insulating film 20 is dry-etched via the contact holes 21a, to form the protection film 20a as shown in FIG. 5(d).

Finally, a transparent conductive film such as an indium tin oxide (ITO) film (thickness: about 50 nm to 200 nm), for example, is formed on the entire substrate having the protection film 20a and the interlayer insulating film 21 formed thereon by sputtering. The transparent conductive film is then subjected to photolithography, wet etching, resist removal, and cleaning, to form the pixel electrodes 22 as shown in FIG. 3.

Thus, the TFT substrate 30a can be fabricated in the manner described above.

<Counter Substrate Fabrication Process>

First, a black-colored photosensitive resin, for example, is applied to the entire of the insulating substrate 10b such as a glass substrate by spin coating or slit coating, and the applied film is exposed to light and developed, to form the black matrix 31 (see FIG. 6(a)) to a thickness of about 1.0 μm.

Subsequently, a red-colored, green-colored, or blue-colored photosensitive resin, for example, is applied to the entire substrate having the black matrix 31 formed thereon by spin coating or slit coating, and the applied film is exposed to light and developed, to form the colored layers 32 of the selected color (e.g., red layers) to a thickness of about 2.0 μm as shown in FIG. 6(a). A similar step is repeated for the other two colors, to form the colored layers 32 of the other two colors (e.g., green layers and blue layers) to a thickness of about 2.0 μm.

A transparent conductive film such as an ITO film, for example, is then deposited on the substrate having the colored layers 32 formed thereon by sputtering, to form the common electrode 33 to a thickness of about 50 nm to 200 nm as shown in FIG. 6(b).

Finally, a photosensitive resin is applied to the entire substrate having the common electrode 33 formed thereon by spin coating or slit coating, and the resultant applied film is exposed to light and developed, to form the photo spacers 34 to a thickness of about 4.0 μm as shown in FIG. 4.

Thus, the counter substrate 40 can be fabricated in the manner described above.

<Liquid Crystal Injection Process>

First, a polyimide resin film is applied by printing to the surface of the TFT substrate 30a fabricated in the TFT substrate fabrication process described above and to the surface of the counter substrate 40 fabricated in the counter substrate fabrication process described above. The resultant applied films are baked and rubbed to form the alignment films.

Subsequently, the seal material 46 made of an ultraviolet (UV) curing resin, an UV-curing and thermosetting resin, etc. is printed in a frame shape on the surface of the counter substrate 40 having the alignment film formed thereon, for example, and then a liquid crystal material is dropped inside the frame of the seal material 46.

Further, the counter substrate 40 having the liquid crystal material dropped thereon and the TFT substrate 30a having the alignment film formed thereon are bonded together under reduced pressure, and then the bonded body is left in the atmospheric pressure to allow the pressure to be applied to the front and back surfaces of the bonded body.

The seal material 46 of the bonded body is irradiated with UV light, and then the bonded body is heated, to set the seal material 46.

Finally, the bonded body having the set seal material 46 is cut by dicing, for example, to remove unnecessary portions thereof.

Thus, the liquid crystal display panel 50 in this embodiment can be fabricated in the manner described above.

Next, experiments practically carried out will be described with reference to FIGS. 7 and 8. FIG. 7 is a graph showing the relationship between the etching time and the element composition ratio in the first experiment. Specifically, in FIG. 7, curve a represents the progression of the atomic ratio of the entire In, curve b represents the progression of the atomic ratio of pure In, curve c represents the progression of the atomic ratio of In in an oxide semiconductor, and curve d represents the progression of the atomic ratio of Si. FIGS. 8(a) and 8(b) are graphs of a TFT characteristic in the second experiment. Specifically, FIG. 8(a) is a graph showing the TFT characteristic in an example of this embodiment, and FIG. 8(b) is a graph showing the TFT characteristic in a comparative example of this embodiment.

First, in the first experiment, a TFT substrate was prepared, which included layers formed up to the nonorganic insulating film without formation of any recess on the surface of the semiconductor layer, unlike the fabrication method in this embodiment. The surface of the prepared TFT substrate was dug down sequentially by dry etching, and the element composition ratio at the etched surface was measured every given etching time by Auger electron spectroscopy. Note that, in this experiment, the gate insulating film is a layered film of a lower silicon nitride film (thickness: about 300 nm) and an upper silicon oxide film (thickness: about 50 nm), the semiconductor layer is an In—Ga—Zn—O oxide semiconductor layer (thickness: about 50 nm), and the inorganic insulating film is a silicon oxide film (thickness: about 200 nm).

As a result of the experiment, as is found from FIG. 7, in the range of the etching time of three to seven minutes at which a neighborhood of the surface of the semiconductor layer was considered exposed. In in the oxide semiconductor (see curve c) was not detected, but pure In (see curve b) was detected. It was therefore presumed that the pure In formed on the surface of the semiconductor layer by being made conductive would affect the ON/OFF ratio of the TFT.

In the second experiment, as an example of this embodiment, a TFT substrate was prepared by performing 35-second over-etching after the formation of the source electrode and the drain electrode to form a recess having a depth of 40 Å on the surface of the semiconductor layer, as in the fabrication method of this embodiment. As a comparative example of this embodiment, a TFT substrate was prepared by performing only 3.5-second over-etching after the formation of the source electrode and the drain electrode to hardly form a recess on the surface of the semiconductor layer.

As a result of the experiment, while the TFT substrate of the example of this embodiment secured a sufficient ON/OFF ratio as shown in FIG. 8(a), the TFT substrate of the comparative example exhibited a characteristic like a conductor having no distinct ON/OFF ratio. This confirmed the effect of the present disclosure exhibited by the recess formed on the surface of the semiconductor layer.

As described above, according to the TFT substrate 30a and the fabrication method for the same of this embodiment, in the recess formation step, the recess R is formed on the channel region C of the semiconductor layer 16 made of an oxide semiconductor to extend in the channel width direction, for reduction or prevention of short-circuiting between the source electrode 19aa and the drain electrode 19b. Thus, with the semiconductor layer 16a having the recess R, when no voltage is being applied between the gate electrode (14a) and the semiconductor layer 16a, a channel current (OFF current) does not easily flow on the surface of the semiconductor layer 16a. When a voltage is being applied between the gate electrode (14a) and the semiconductor layer 16a, a channel current (ON current) flows on the surface of the semiconductor layer 16a via the bottom of the recess R of the semiconductor layer 16a. Therefore, since it is possible to suppress or reduce the OFF current while maintaining the ON current, a good ON/OFF ratio can be secured in the TFT 5a using an oxide semiconductor layer. Moreover, in the TFT substrate 30a, having the semiconductor layer 16a made of an oxide semiconductor, the TFT 5a having good characteristics such as high high mobility, high reliability, reduced OFF current can be implemented.

Also, according to the TFT substrate 30a and the fabrication method for the same of this embodiment, in the recess formation step, the recess R is formed on the entire of the portion of the semiconductor layer 16a that is not covered with the source electrode 19aa or the drain electrode 19b by etching the semiconductor layer 16 using the source electrode 19aa and the drain electrode 19b as a mask. This eliminates the necessity of forming the mask for formation of the recess R separately, and thus can suppress or reduce increases in the number of fabrication steps and the fabrication cost.

According to the TFT substrate 30a of this embodiment, the semiconductor layer 16a has semiconductivity at the bottom of the recess R and has conductivity at the outer edges of the recess R. Therefore, while a channel current (ON current) is allowed to flow via the bottom of the recess R of the semiconductor layer 16a, which has semiconductivity, when a voltage is being applied between the gate electrode (14a) and the semiconductor layer 16a, flow of a channel current (OFF current) can be suppressed or reduced by the recess R of the semiconductor layer 16a and the bottom of the recess R having semiconductivity when no voltage is being applied between the gate electrode (14a) and the semiconductor layer 16a.

### Embodiment 2

FIG. 9 is a cross-sectional view of a TFT substrate 30b of this embodiment. Note that, in this and the subsequent embodiments, the same components as those in FIGS. 1 to 8 are denoted by the same reference characters, and detailed description thereof is omitted.

In Embodiment 1, illustrated was the TFT substrate 30a including the TFT 5a in which the gate line, the gate electrode, and the capacitor line had a two-layer structure, and the first metal layer of each of the source electrode and the drain electrode protruded from the second metal layer thereof at its end facing the channel region. In this embodiment, illustrated will be the TFT substrate 30b including a TFT 5b in which the gate line, the gate electrode, and the capacitor line have a three-layer structure, and the first and second metal layers of each of the source electrode and the drain electrode have roughly the same shape.

Specifically, as shown in FIG. 9, in the TFT substrate 30b, the TFT 5b includes: the gate electrode (14a) provided on the insulating substrate 10a; the gate insulating film 15 provided to cover the gate electrode (14a); a semiconductor layer 16b provided on the gate insulating film 15 with the channel region C arranged to lie above the gate electrode (14a); and the source electrode 19aa and the drain electrode 19b provided on the semiconductor layer 16b to be spaced from each other with the channel region C therebetween.

The gate electrode (14a) has a three-layer structure of a first metal layer 11a using a titanium film, a second metal layer 12a using an aluminum-silicon alloy film, and a third metal layer 13a using a titanium film, for example, formed in this order as shown in FIG. 9. Like the gate electrode (14a), the capacitor line 14b has a three-layer structure of a first metal layer 11b, a second metal layer 12b, and a third metal layer 13b formed in this order as shown in FIG. 9.

The end of each of first metal layers 17c and 17d of the source electrode 19aa and the drain electrode 19b is roughly in line with the end of the corresponding second metal layer 18a or 18b as shown in FIG. 9.

The semiconductor layer 16b is made of an In—Ga—Zn—O oxide semiconductor. A recess (R) is formed on the surface of the channel region C of the semiconductor layer 16b located between the source electrode 19aa and the drain electrode 19b to extend in the channel width direction.

The TFT substrate 30b having the above configuration can be fabricated by increasing the number of layers of the metal layered film from two to three in the gate formation step of the fabrication method described in Embodiment 1, and also patterning the metal layered film of the first metal film and the second metal film at one time in the source/drain formation step.

According to the TFT substrate 30b and the fabrication method for the same of this embodiment, as in Embodiment 1, the recess (R) is formed on the surface of the channel region C of the semiconductor layer 16b made of an oxide semiconductor to extend in the channel width direction. Therefore, a good ON/OFF ratio can be obtained in the TFT 5b using an oxide semiconductor layer.

### Embodiment 3

FIG. 10 is a cross-sectional view of a TFT substrate 30c of this embodiment.

In the above embodiments, illustrated were the fabrication methods for the TFT substrates 30a and 30b in which a recess was formed on the semiconductor layer using the source electrode and the drain electrode as a mask. In this embodiment, illustrated will be a fabrication method for the TFT substrate 30c in which a recess is formed on the semiconductor layer without use of the source electrode and the drain electrode as a mask.

Specifically, as shown in FIG. 10, in the TFT substrate 30c, the TFT 5c includes: the gate electrode (14a) provided on the insulating substrate 10a; the gate insulating film 15 provided to cover the gate electrode (14a); a semiconductor layer 16c provided on the gate insulating film 15 with the channel region C arranged to lie above the gate electrode (14a); and the source electrode 19aa and the drain electrode 19b provided on the semiconductor layer 16c to be spaced from each other with the channel region C therebetween.

As shown in FIG. 10, on the semiconductor layer 16c, a groove-shaped recess R is formed on the surface of the channel region C exposed between the source electrode 19aa and the drain electrode 19b to extend in the channel width direction.

The TFT substrate 30c having the above configuration can be fabricated in the following manner: after the formation of the source electrode 19aa and the drain electrode 19b by patterning the metal layered film of the first metal film and the second metal film at one time in the source/drain formation step of the fabrication method described in Embodiment 2, a resist is formed to expose the portion on the channel region C of the semiconductor layer (16c) where the recess R is to be formed, and an upper portion of the semiconductor layer (16c) is etched away via the resist to form the recess R.

According to the TFT substrate 30c and the fabrication method for the same of this embodiment, as in Embodiment 1, the recess R is formed on the surface of the channel region C of the semiconductor layer 16c made of an oxide semiconductor to extend in the channel width direction. Therefore, a good ON/OFF ratio can be secured in the TFT 5c using an oxide semiconductor layer.

Although the interconnects for display (gate lines, capacitor lines, source lines) and corresponding electrodes having a two-layer or three-layer structure were described in the above embodiments, such interconnects and electrodes may have any other layered structure or a single-layer structure using a titanium film, etc., and various types of metal films other than those mentioned above may be used.

Although the liquid crystal display panel was described as the display panel including the TFT substrate in the above embodiments, the present disclosure is also applicable to other display panels such as an organic electroluminescence (EL) panel, an inorganic EL display panel, and an electrophoresis display panel.

Although the In—Ga—Zn—O oxide semiconductor layer was described in the above embodiments, the present disclosure is also applicable to oxide semiconductor layers of In—Si—Zn—O, In—Al—Zn—O, Sn—Si—Zn—O, Sn—Al—Zn—O, Sn—Ga—Zn—O, Ga—Si—Zn—O, Ga—Al—Zn—O, In—Cu—Zn—O, Sn—Cu—Zn—O, Zn—O, In—O, In—Zn—O, etc.

Although the TFT substrate designating the electrode of the TFT connected to the pixel electrode as the drain electrode was described in the above embodiments, the present disclosure is also applicable to a TFT substrate designating the electrode of the TFT connected to the pixel electrode as the source electrode.

### INDUSTRIAL APPLICABILITY

As described above, since a good ON/OFF ratio can be secured in TFTs using an oxide semiconductor layer, the present disclosure is useful for TFT substrates constituting various types of display panels.

### DESCRIPTION OF REFERENCE CHARACTERS

C Channel region
R Recess
5a-5c TFT
10a Insulating substrate
14a Gate electrode
15 Gate insulating film
16, 16a-16c Semiconductor layer
19aa Source electrode
19b drain electrode
30a-30c TFT substrate

1. A thin film transistor substrate, comprising a thin film transistor including:
a gate electrode provided on a substrate;
a gate insulating film provided to cover the gate electrode;
a semiconductor layer made of an oxide semiconductor provided on the gate insulating film with a channel region arranged to lie above the gate electrode; and
a source electrode and a drain electrode provided on the semiconductor layer to be spaced from each other with the channel region therebetween,
wherein
a recess is provided on the surface of the channel region of the semiconductor layer to extend in a channel width direction.

2. The thin film transistor substrate of claim 1, wherein
the recess is provided on the entire of a portion of the semiconductor layer that is not covered with the source electrode or the drain electrode.

3. The thin film transistor substrate of claim 1, wherein
the semiconductor layer has semiconductivity at the bottom of the recess and has conductivity at edges of the recess.

4. A fabrication method for a thin film transistor substrate, comprising:
a gate formation step of forming a gate electrode on a substrate;
a semiconductor layer formation step of, after formation of a gate insulating film to cover the gate electrode, forming a semiconductor layer made of an oxide semiconductor on the gate insulating film with a channel region arranged to lie above the gate electrode; and
a source/drain formation step of forming a source electrode and a drain electrode on the semiconductor layer to be spaced from each other with the channel region therebetween,
wherein
the method further comprises a recess formation step of forming a recess on the surface of the channel region of the semiconductor layer to extend in a channel width direction, to reduce or prevent short-circuiting between the source electrode and the drain electrode.

5. The fabrication method for a thin film transistor substrate of claim 4, wherein
in the recess formation step, the semiconductor layer is etched using the source electrode and the drain electrode as a mask.
